(19) United States
(12) Patent Application Publication
(10) Pub. No.: US 2023/0040683 A1
(43) Pub. Date: Feb. 9, 2023

(54) PLASMA-GENERATING NOZZLE AND PLASMA DEVICE INCLUDING SAME

(71) Applicant: PlasmaDent Inc., Columbia, MO (US)

(72) Inventors: Letian ZHANG, Columbia, MO (US); Hao LI, Columbia, MO (US)

(73) Assignee: PlasmaDent Inc., Columbia, MO (US)

(21) Appl. No.: 17/396,445

(22) Filed: Aug. 6, 2021

(51) Int. Cl. H01J 37/32; B05B 1/00

(52) U.S. Cl. CPC H01J 37/32568; H01J 37/32844; H01J 37/3244; B05B 1/005; H01J 2237/002

(57) ABSTRACT

A plasma-generating nozzle and a plasma device including the plasma-generating nozzle are provided. The plasma-generating nozzle includes a plasma-generating channel, a cooling channel at least partially surrounding the plasma-generating channel, and a pair of electrodes partially disposed in the plasma-generating channel for generating plasma. The plasma device includes a housing enclosing a plasma treatment space and a component space, and the plasma-generating nozzle removable disposed in the plasma treatment space.

### TECHNICAL FIELD

The present disclosure generally relates to a device for performing plasma treatment to a material sample. More specifically, the present disclosure relates to a plasma-generating nozzle and a plasma device including the plasma-generating nozzle.

### BACKGROUND

The statements in this section merely provide background information related to the present disclosure and may not constitute prior art.

Low temperature plasma technology has been employed to initiate, promote, control, and catalyze various complex behaviors and responses in biological systems. More importantly, low temperature plasma can be tuned to achieve a desired medical effect, especially in medical sterilization, dental restoration, wound healing, and treatment of skin diseases. However, current plasma generators are generally bulky, inflexible, and require relatively high voltage to ignite the plasma, and the plasma flame or jet that is generated are too large and instable in size. These drawbacks pose difficulties when indirectly delivering the plasma flame to a desired but hard to reach treatment site.

In addition, during operation of the plasma generators, the temperature of electrical components included in the generators may rise due to the high voltage required for igniting and maintaining the plasma. For the electrical components in the plasma generators to operate, cooling gases or fluids are usually supplied, or extra fans are installed.

Furthermore, during operation of the plasma generators, ozone generated by the plasma may escape outside of a plasma-generating chamber, contaminating an ambient environment of the plasma generators.

### SUMMARY

There is a need to provide a new and improved device for targeted delivery of low temperature plasma to an intended surface. There is also a need to provide a new and improved device with a controlled gas flow to cool down the components inside the device and to reduce ozone and other gas by-products during plasma generation.

According to one aspect of the present disclosure, a plasma-generating nozzle is provided. The plasma-generating nozzle includes a plasma-generating channel, a cooling channel at least partially surrounding the plasma-generating channel, and a pair of electrodes partially disposed in the plasma-generating channel for generating plasma.

According to one aspect of the present disclosure, a plasma device is provided. The plasma device includes a housing enclosing a plasma treatment space and a component space, and a plasma-generating nozzle removably disposed in the plasma treatment space. The plasma treatment space has a negative pressure during operation of the plasma device.

### BRIEF DESCRIPTION OF DRAWINGS

FIG. 1A schematically illustrates a perspective view of a plasma-generating nozzle, consistent with an embodiment of the present disclosure.

FIG. 1B schematically illustrates a front view of the plasma-generating nozzle of FIG. 1A.

FIG. 1C schematically illustrates a side view of the plasma-generating nozzle of FIG. 1A.

FIG. 1D schematically illustrates a top view of the plasma-generating nozzle of FIG. 1A.

FIG. 1E schematically illustrates a bottom view of the plasma-generating nozzle of FIG. 1A.

FIG. 1F schematically illustrates a sectional view of the plasma-generating nozzle of FIG. 1D, along line A-A′ in FIG. 1D.

FIG. 1G schematically illustrates a sectional view of the plasma-generating nozzle of FIG. 1F, along line B-B′ in FIG. 1F.

FIG. 2 schematically illustrates an enlarged side view of a pair of electrodes connected to an electrode holder, consistent with an embodiment of the present disclosure.

FIG. 3A schematically illustrates an enlarged side view of a pair of electrodes connected to an electrode holder, consistent with another embodiment of the present disclosure.

FIG. 3B schematically illustrates a further enlarged side view of tips of the electrodes of FIG. 3A.

FIG. 4A schematically illustrates a perspective front view of a plasma device with a front cover, consistent with an embodiment of the present disclosure.

FIG. 4B schematically illustrates a perspective front view of the plasma device of FIG. 4A, with the front cover being removed.

FIG. 4C schematically illustrates a perspective back view of the plasma device of FIG. 4A, with a back panel.

FIG. 4D schematically illustrates a perspective back view of the plasma device of FIG. 4A, with part of the back panel being removed.

FIG. 4E schematically illustrates a sectional view of the plasma device of FIG. 4B, along line C-C′ in FIG. 4B.

FIG. 5 schematically illustrates an electrical system of a plasma device 400, consistent with an embodiment of the present disclosure.

FIG. 6 schematically illustrates a sectional view of a plasma device with air flows, consistent with an embodiment of the present disclosure.

FIG. 7 schematically illustrates a sectional view of a plasma device, consistent with another embodiment of the present disclosure.

FIG. 8A shows top views of three different plasma-generating nozzles.

FIG. 8B is a photo showing a bottom view of a plasma-generating nozzle without cooling channel after a plasma generation process.

FIG. 8C is a graph showing plasma temperatures generated by samples with different duty cycles of exhaust fans and different inlet openings of cooling channels.

### DETAILED DESCRIPTION

The text below provides a detailed description of the present disclosure in conjunction with specific embodiments illustrated in the attached drawings. However, these embodiments do not limit the present disclosure. The scope of protection for the present disclosure covers changes made to the structure, method, or function by persons having ordinary skill in the art on the basis of these embodiments.

To facilitate the presentation of the drawings in the present disclosure, the sizes of certain structures or portions may be enlarged relative to other structures or portions. Therefore, the drawings in the present application are only for the purpose of illustrating the basic structure of the subject matter of the present application. The same numbers in different drawings represent the same or similar elements unless otherwise represented.

Additionally, terms in the text indicating relative spatial position, such as “front,” “back,” “upper,” “above,” “lower,” “below,” and so forth, are used for explanatory purposes in describing the relationship between a unit or feature depicted in a drawing with another unit or feature therein. Terms indicating relative spatial position may refer to positions other than those depicted in the drawings when a device is being used or operated. For example, if a device shown in a drawing is flipped over, a unit which is described as being positioned “below” or “under” another unit or feature will be located “above” the other unit or feature. Therefore, the illustrative term “below” may include positions both above and below. A device may be oriented in other ways (rotated 90 degrees or facing another direction), and descriptive terms that appear in the text and are related to space should be interpreted accordingly. When a component or layer is said to be “above” another member or layer or “connected to” another member or layer, it may be directly above the other member or layer or directly connected to the other member or layer, or there may be an intermediate component or layer.

The present disclosure addresses one or more disadvantages associated with conventional low temperature plasma devices. In one aspect, the present disclosure provides a plasma device for performing plasma treatment on a material sample. The plasma device may include a housing enclosing a plasma treatment space in which a plasma-generating nozzle for igniting and sustaining a plasma jet is removably disposed, and a component space in which a plurality of electrical components is disposed. The plasma-generating nozzle may be connected to an intake fan to receive a working gas for plasma generation and for cooling down electrodes used for generating the plasma. Exhaust gas resulting from the plasma generated in the plasma-generating space may be forced by an exhaust fan to flow from the plasma-generating space to the component space and may pass through the plurality of electrical components in the component space before being vented outside of the plasma device. Thereby, the electrical components may be cooled down by the exhaust gas resulted from the plasma generation, and thus no additional cooling fluid or cooling fan is needed.

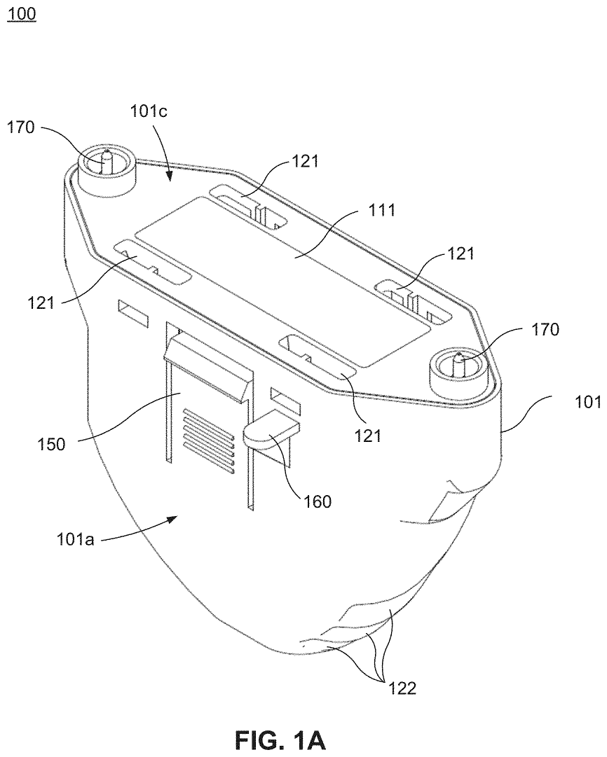

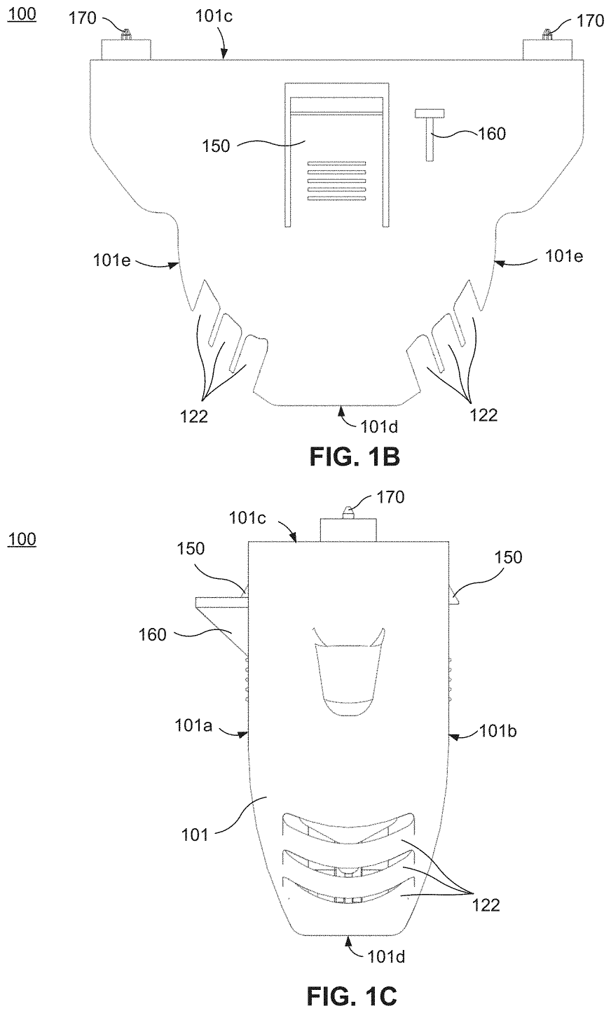

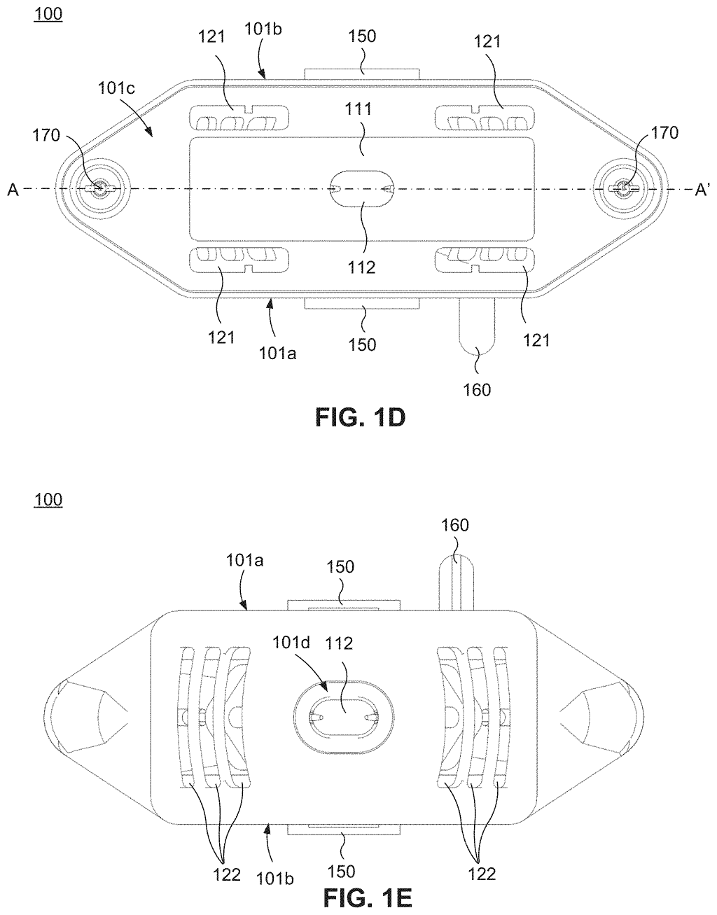

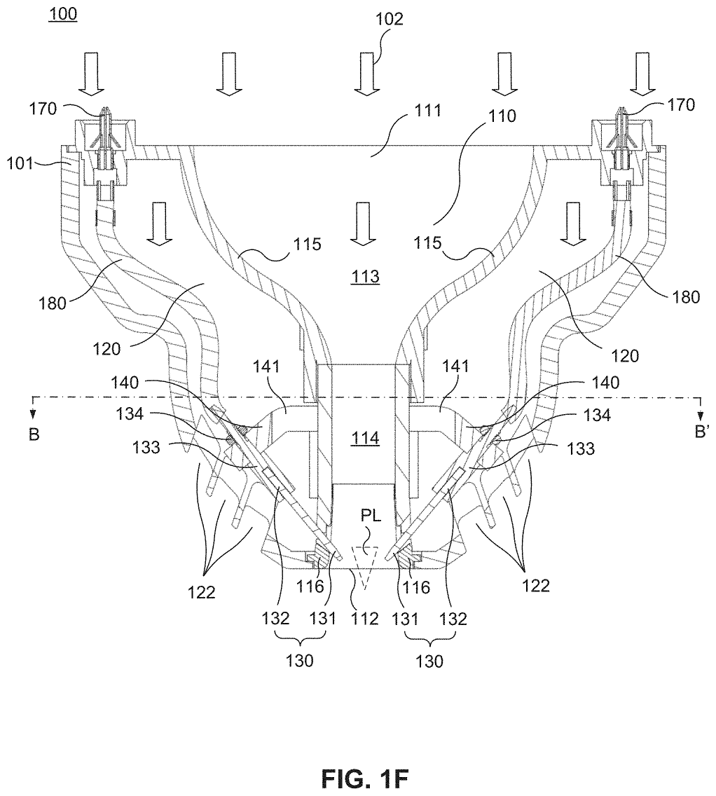

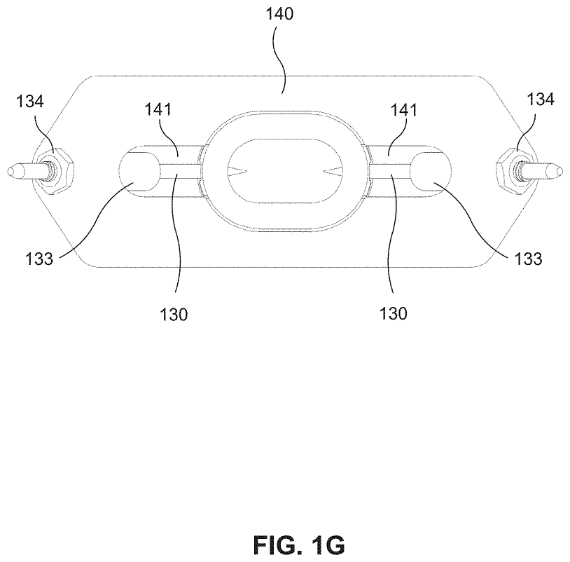

FIGS. 1A to 1G schematically illustrate a plasma-generating nozzle 100, consistent with an embodiment of the present disclosure. In particular, FIG. 1A schematically illustrates a perspective view of the plasma-generating nozzle 100; FIG. 1B schematically illustrates a front view of the plasma-generating nozzle 100; FIG. 1C schematically illustrates a side view of the plasma-generating nozzle 100; FIG. 1D schematically illustrates a top view of the plasma-generating nozzle 100; FIG. 1E schematically illustrates a bottom view of the plasma-generating nozzle 100; FIG. 1F schematically illustrates a sectional view of the plasma-generating nozzle 100 along line A-A′ in FIG. 1D; and FIG. 1G schematically illustrates a sectional view of the plasma-generating nozzle 100 along line B-B′ in FIG. 1F. For ease of reference, nozzle housing 101 and electrical cables 180 in FIG. 1G are omitted. The configuration plasma-generating nozzle 100 illustrated in FIGS. 1A to 1G is an example of the present embodiment. In some alternative embodiments, the numbers, shapes, sizes, and arrangements of the parts may vary.

As illustrated in FIGS. 1A to 1G, the plasma-generating nozzle 100 includes a plasma-generating channel 110, a cooling channel 120 at least partially surrounding the plasma-generating channel 110, and a pair of electrodes 130 partially disposed in the plasma-generating channel 110 for generating plasma. Specifically, the plasma-generating nozzle 100 includes a nozzle housing 101 enclosing the plasma-generating channel 110, the cooling channel 120 disposed adjacent to the plasma-generating channel 110, as well as the pair of electrodes 130 and an electrode holder 140 disposed at a lower portion of the nozzle housing 101. The nozzle housing 101 may be made from, for example, plastic. In the plasma-generating nozzle 100 according to the embodiment illustrated in FIGS. 1A to 1G, the cooling channel 120 at least partially surrounds the plasma-generating channel 110. Alternatively, in other embodiments, the cooling channel 120 may only contact a portion of a sidewall 115 of the plasma-generating channel 110. The plasma-generating nozzle 100 further includes a depressible button 150 disposed on at least one of a front surface 101a and a back surface 101b of the nozzle housing 101, a pressing structure 160 disposed on the front surface 101a of the nozzle housing 101, a pair of pin contacts 170 disposed on a top surface 101c of the nozzle housing 101, and a pair of electrical cables 180 disposed in the cooling channel 120.

As illustrated in the sectional view of FIG. 1F, the plasma-generating channel 110 includes a first gas inlet opening 111 formed on the top surface 101c of the nozzle housing 101 and a first gas outlet opening 112 formed on a bottom surface 101d of nozzle housing 101. The first gas inlet opening 111 is configured to receive a working gas 102 for plasma generation. The working gas 102 may contain, for example, air, argon, helium, nitrogen, or a mixture thereof. A flow rate of the working gas 102 may range from 25 LPM to 350 LPM, or preferably from 140 LPM to 210 LPM. A humidity rate of the working gas 102 may range from 10% to 75%, or preferably from 30% to 50%. The first gas outlet opening 112 is configured to discharge the working gas 102 as well as other gases, such as ozone, generated by the plasma.

As illustrated in the top view of FIG. 1D and the bottom view of FIG. 1E, in the plasma-generating nozzle 100 according to the present embodiment, the shape of the first gas inlet opening 111 is rectangle, and the shape of the first gas outlet opening 112 is oval. Alternatively, in other embodiments, the first gas inlet opening 111 and the first gas outlet opening 112 may have other shapes, such as square, circular, etc.

As illustrated in the sectional view of FIG. 1F, the cooling channel 120 includes at least one second gas inlet opening 121 formed on the top surface 101c of the nozzle housing 101 and at least one second gas outlet opening 122 formed on at least one side surface 101e of the nozzle housing 101. The second gas inlet opening 121 is configured to receive the working gas 102 used for cooling the electrodes 130 and the electrode holder 140, disposed in the cooling channel 120. The second gas outlet opening 122 is configured to discharge the working gas 102.

As illustrated in the top view of FIG. 1D and the bottom view of FIG. 1E, in the plasma-generating nozzle 100 according to the present embodiment, there are four second gas inlet openings 121 formed on the top surface 101c of the nozzle housing 101, and three second gas outlet openings 122 formed on each one of the side surfaces 101e of the nozzle housing 101. Alternatively, in other embodiments, the numbers of the second gas inlet openings 121 and the second gas outlet openings 122 may vary.

As illustrated in the sectional view of FIG. 1F, the pair of electrodes 130 are disposed at a lower portion of the nozzle housing 101. The pair of electrodes 130 may be needle-shaped or cylinder-shaped. Each of the electrodes 130 has a tip 131 and a connection end 132. At least a portion of each of the electrode tips 131 is disposed at the first gas outlet opening 112 of the plasma-generating channel 110. At least a portion of each of the connection ends 132 is disposed at the second gas outlet opening 122 of the cooling channel 120. Each of the electrodes 130 may be made from a metal such as, for example, platinum, tungsten, or tungsten alloy.

During operation of the plasma-generating nozzle 100, an alternating current (AC) electrical voltage may be applied between the pair of electrodes 130, and the working gas 102 containing air, argon, helium, nitrogen, or a mixture thereof, may be supplied to the plasma-generating channel 110 and the cooling channel 120. Thereby, a brush-shaped plasma (PL) jet (labeled in FIG. 1F as “PL”) may be generated in the vicinity of the electrode tips 131.

The shape and size of the plasma jet PL generated by the pair of electrodes 130 may be affected by the flow of the working gas 102 in the plasma-generating nozzle 100. For example, if there are obstacles in the plasma-generating channel 110, turbulence may be created in the gas flow. As a result, the plasma jet PL may become irregular and a distribution of active species (such as ions, radicals, electrons, excited-state (e.g., metastable) species, molecular fragments, photons, etc.) in the plasma jet PL may become non-uniform. Consequently, the effectiveness of a material treatment by the plasma device including the plasma-generating nozzle 100 may be reduced and the outcome of the material that is treated may be negatively affected. In the plasma-generating nozzle 100 according to the present embodiment, the plasma-generating channel 110 is free of any obstacles, thereby facilitating the generation of uniformed plasma jet PL.

According to the embodiments of the present disclosure, a size of the first gas inlet opening 111 of the plasma-generating channel 110 may be larger than a size of the first gas outlet opening 112 of the plasma-generating channel 110. For example, as illustrated in the top view of FIG. 1D, in the plasma-generating nozzle 100 according to the present embodiment, the width and the length of the first gas inlet opening 111 along the top surface 101c of the nozzle housing 101 are respectively larger than the width and the length of the first gas outlet opening 112 along the bottom surface 101d of the nozzle housing 101. In addition, as illustrated in the sectional view of FIG. 1F, in the plasma-generating nozzle 100 according to the present embodiment, the plasma-generating channel 110 includes a funnel shaped part 113 connected to the first gas inlet opening 111 and a cylindrical shaped part 114 connected between the funnel shaped part 113 and the first gas outlet opening 112. The larger gas inlet opening 111 and the funnel shaped part 113 of the plasma-generating channel 110 may allow for gathering of the flow of working gas 102, thereby increasing a length of the plasma jet PL generated by the pair of electrodes 130.

As illustrated in FIG. 1F, in the plasma-generating channel 110 according to the present embodiment, the cylindrical shaped part 114 is connected between the funnel shaped part 113 and the first gas outlet opening 112. Alternatively, in other embodiments, the plasma-generating channel 110 may not include the cylindrical shaped part 114. That is, in some embodiments, the plasma-generating channel 110 may only include the funnel shaped part 113 connected between the first gas inlet opening 111 and the first gas outlet opening 112.

In addition, in the plasma-generating channel 110 according to the present embodiment, a cross section of the cylindrical shaped part 114 is oval. Alternatively, in other embodiments, the cross section of the cylindrical shaped part 114 may have other shapes.

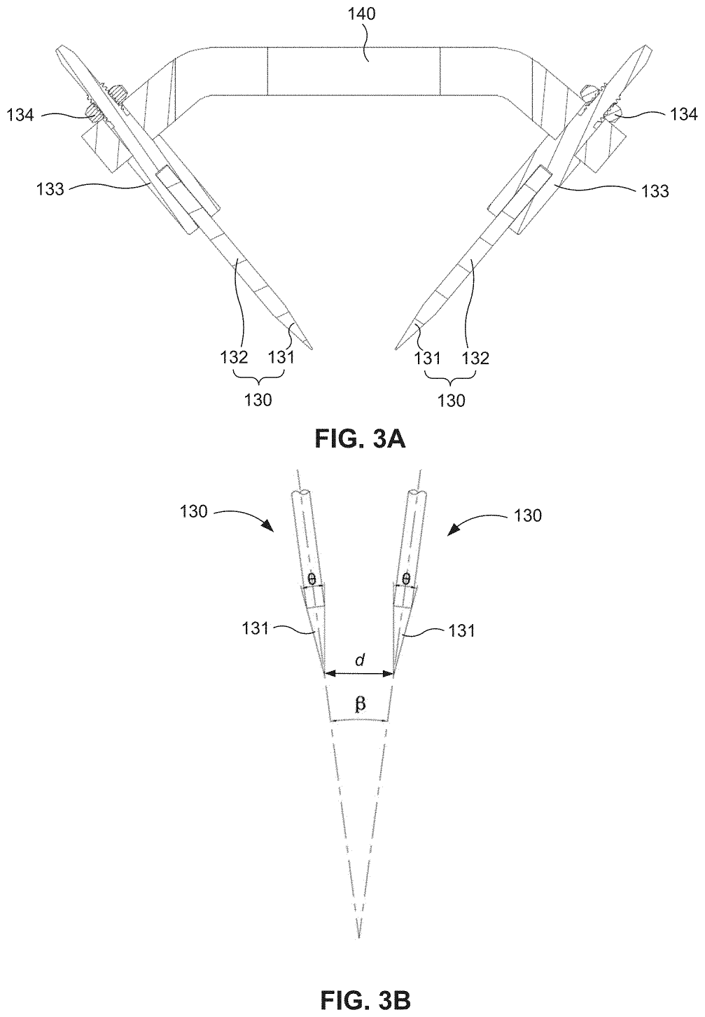

As illustrated in the sectional view of FIG. 1F, the electrode holder 140 is disposed at the lower portion of the cooling channel 120 and fixed to the sidewall of the plasma-generating channel 110. A pair of electrode connectors 133 are fixed to the electrode holder 140. As illustrated in the sectional views of FIGS. 1F and 1G, the electrode holder 140 includes a plurality of openings 141 for passing the working gas 102. As a result, the working gas 102, which is used as a cooling gas, may flow through the openings 141 to cool the electrodes 130, thereby increasing the cooling efficiency of the cooling channel 120. The electrode holder 140 may be made from a rigid dielectric material with heat resistance and thermal conductivity. For example, the electrode holder 140 may be made from a ceramic material such as aluminum nitride, aluminum oxide, etc. The rigid electrode holder 140 can maintain the electrodes 130 at a predetermined angle and a predetermined distance from each other. As will be explained in more detail with respect to FIGS. 3A and 3B, the distance between the electrodes 130 may be adjusted to help balance the appropriate size of the plasma jet with reasonable energy consumption. Because the electrode holder 140 of the present embodiments allows the distance between the electrodes 130 to be accurately controlled, the size of the plasma jet and the energy consumption can be accurately controlled as well, thereby ensuring the stability of plasma generation. In addition, because the ceramic electrode holder 140 has good thermal conductivity, the ceramic electrode holder 140 may serve as a heat sink to cool down the electrodes 130 and extend the life span of the electrodes 130.

In some embodiments, the electrodes 130 may be directly connected to and fixed to the electrode holder 140. Alternatively, in the embodiment illustrated in FIG. 1F, the plasma-generating nozzle 100 further includes the pair of electrode connectors 133 configured to secure the pair of electrodes 130 to the electrode holder 140. Each of the electrode connectors 133 may be made from an electrically conductive material such as copper, silver, stainless steel, nickel, chromium, aluminum, constantan, or an alloy or combination of the electrically conductive materials. For example, the electrode connectors 133 may be secured to the electrode holder 140 by a pair of nuts 134. Additionally, a cooling mechanism, such as heat sink, heat pipe, Peltier module, etc. may also be attached to the electrodes 130 and electrode connectors 133 to help further cooling down the electrodes 130 and as a result reduce the temperature of the plasma jet PL.

In the plasma-generating nozzle 100 according to the present embodiment, the plasma-generating channel 110 for generating the plasma is separated from the cooling channel 120, which may provide a stable and uniform brush-shaped plasma jet PL, and prevent the gas turbulence in the cooling channel 120 from interfering with the gas flow in the plasma-generating channel 110. To cool the electrodes 130, the flow of working gas 102 (used as the cooling gas) may pass through the electrodes 130, the electrode holder 140, and the electrode connectors 133, if any. The electrodes 130, the electrode holder 140, and the electrode connectors 133 may have complex structures that may cause turbulence in the cooling channel 120. Insulating the plasma-generating channel 110 from the cooling channel 120 may help protect the plasma generation form the turbulence generated in the cooling channel 120.

The cooling channel 120 provides multiple functions. First, the cooling gas in the cooling channel 120 may lower the temperature of the electrodes 130 to extend the life span of the electrodes 130. Second, lowering temperature of the electrodes 130 may further reduce the temperature of plasma jet PL.

The temperature of the plasma jet PL may be affected by the gas flow in the plasma-generating channel 110 and the gas flow in the cooling channel 120, which may be respectively affected by the size of first gas inlet opening 111 and the size of multiple second gas inlet openings 121. Thus, by varying the relative sizes between the first gas inlet opening 111 and the second gas inlet openings 121, plasma jets of different temperatures may be generated.

The depressible button 150 may be disposed on at least one of the front surface 101a and the back surface 101b of the nozzle housing 101. As illustrated in FIGS. 1A to 1C, in the plasma-generating nozzle 100 according to present embodiment, the depressible button 150 is disposed on each one of the front surface 101a and the back surface 101b of the nozzle housing 101. During the installation of the plasma-generating nozzle 100 to the plasma device, a user may press the depressible buttons 150, such that the plasma-generating nozzle 100 may be attached to the plasma device. When the plasma-generating nozzle 100 is attached to the plasma device, a user may press the depressible buttons 150 to remove the plasma-generating nozzle 100 from the plasma device.

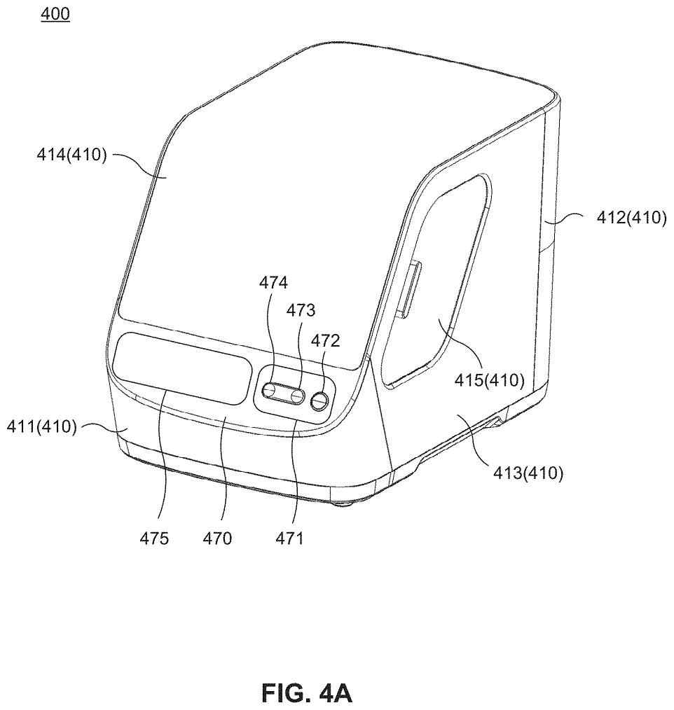

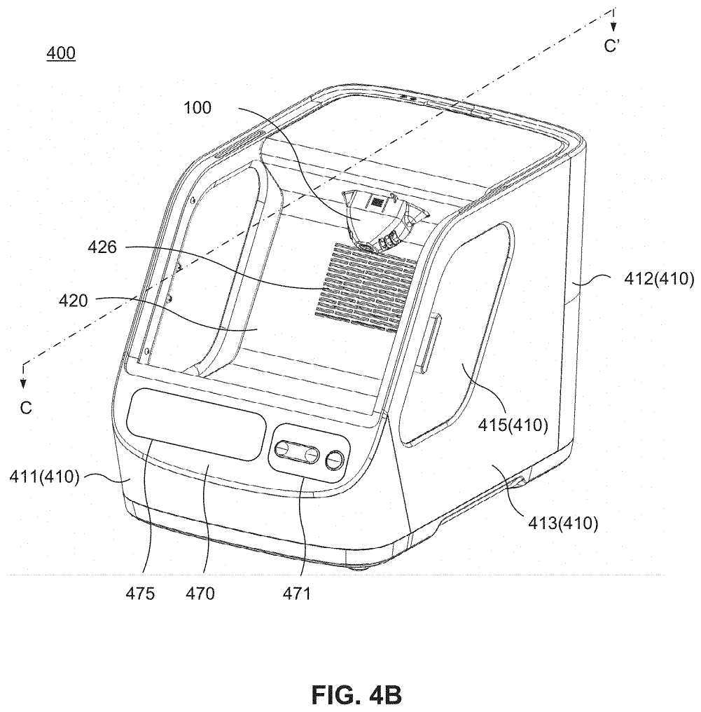

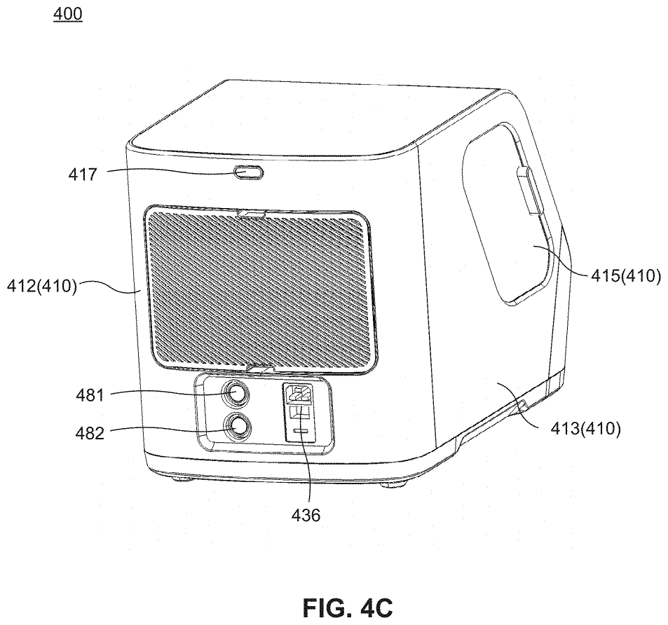

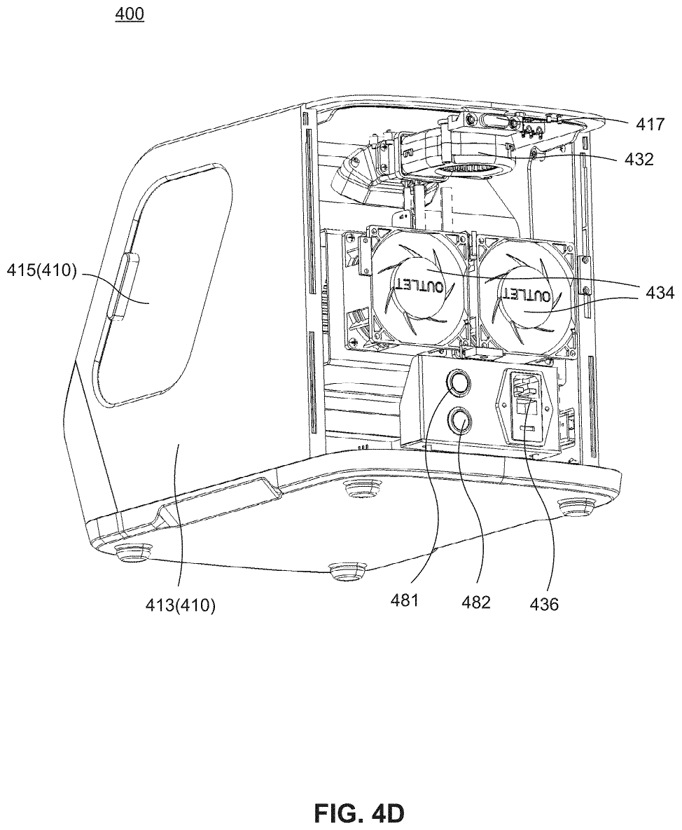

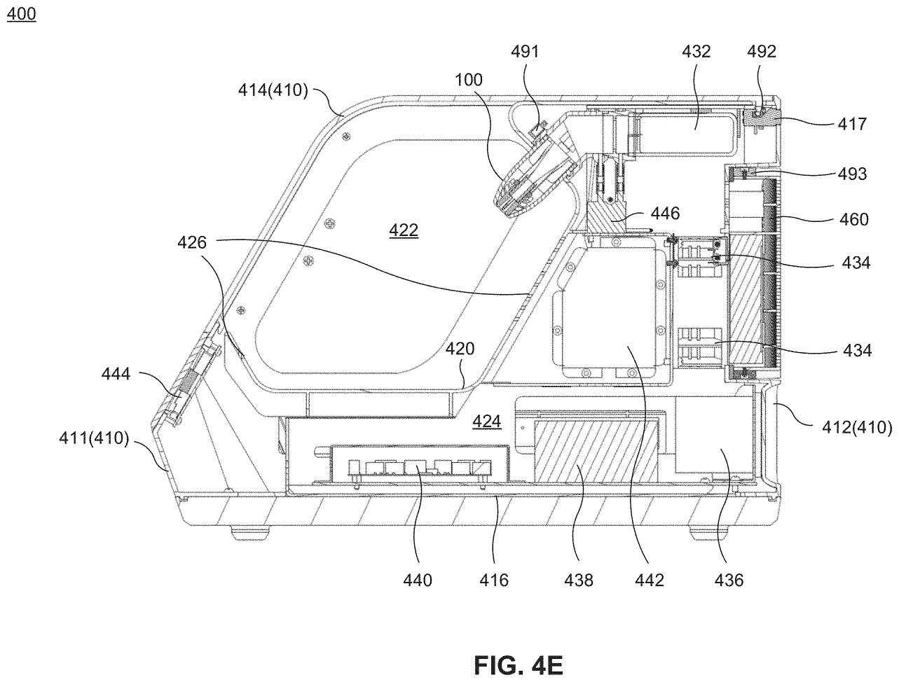

As illustrated in FIGS. 1A and 1B, the pressing structure 160 is disposed on the front surface 101a of the nozzle housing 101. When the plasma-generating nozzle 100 is installed in the plasma device, the pressing structure 160 may press against a limit switch disposed in the plasma device. The limit switch may function an installation sensor (such the first installation sensor 491 in FIG. 4E), which may be activated when being pressed by the pressing structure 160. When the installation sensor is activated, the installation sensor may transmit a signal to a main controller of the plasma device to indicate that the plasma-generating nozzle 100 has been installed.

As illustrated in FIGS. 1A and 1F, the pair of pin contacts 170 are disposed on the top surface 101c of the nozzle housing 101 and is electrically connectable to a power supply. The pair of electrical cables 180 are disposed in the cooling channel 120 and are electrically connected between the pair of pin contacts 170 and the pair of electrodes 130. When the plasma-generating nozzle 100 is fully installed in the plasma device, the pin contacts 170 are electrically connected to the power supply to transfer power supplied by the power supply to the electrodes 130 via the electrical cables 180.

In some embodiments, at least a part of the plasma-generating channel 110 surrounding the electrode tips 131 may include a dielectric material. In the embodiment illustrated in FIG. 1F, a dielectric material part 116 is disposed at the bottom of the plasma-generating channel 110 to surround the electrode tips 131. The dielectric material part 116 may function to protect the sidewall 115 of the plasma-generating channel 110 from the high temperature and being bombarded by various species generated by the plasma, thereby extending the life span of the plasma-generating nozzle 100. The dielectric material part 116 can be made of any dielectric material but preferable ceramic material.

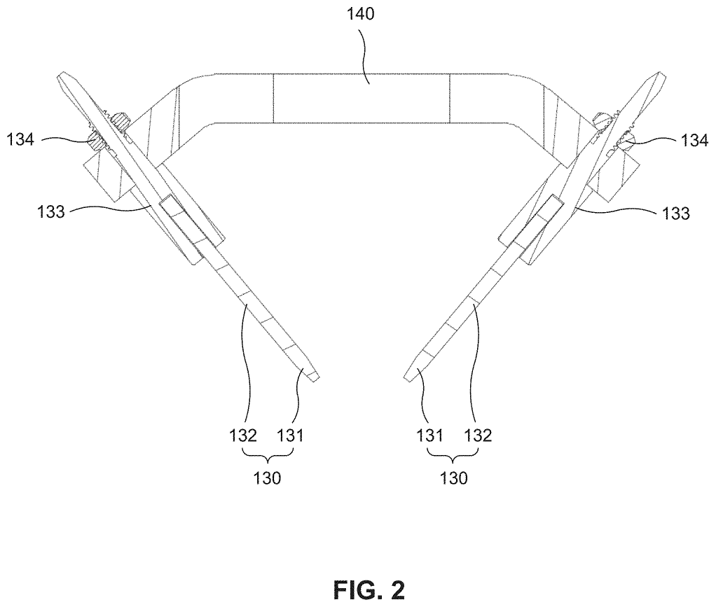

FIG. 2 schematically illustrates an enlarged side view of the electrodes 130 (blunt tip) connected to the electrode holder 140 via the electrode connectors 133, consistent with an embodiment of the present disclosure. The tips 131 of the electrodes 130 may be sharp or blunt.

FIG. 3A schematically illustrates an enlarged side view of electrodes 130 (sharp tip) connected to the electrode holder 140 via the electrode connectors 133, consistent with an alternative embodiment of the present disclosure. FIG. 3B schematically illustrates a further enlarged side view of tips 131 of the electrodes 130.

As illustrated in FIGS. 3A and 3B, the tips 131 of the electrodes 130 are sharp. A grind angle θ of each of the tips 131 may range from 0° to 180°, or preferably 15°. The needle-shaped electrodes 130 may help creating a strong electric field gradient, which may help initiate the plasma generation process.

An angle β between the electrode tips 131 may range from θ to 180°, where θ is the grind angle of each of the electrode tips 131. A distance d between proximal ends of the electrode tips 131 may range from 2 mm to 10 mm, or preferably 6 mm. Increasing the distance d between the electrode tips 131 may help increasing the size of the plasma jet PL generated in the vicinity of the electrode tips 131. However, if the distance d between the electrode tips 131 is greater, more energy may be needed to initiate and maintain the plasma generation process. Therefore, the distance d may be chosen to help balancing the appropriate size of the plasma jet with reasonable energy consumption.

FIGS. 4A to 4F schematically illustrate a plasma device 400, consistent with an embodiment of the present disclosure. In particular, FIG. 4A schematically illustrates a perspective front view of the plasma device 400 with a front cover 414; FIG. 4B schematically illustrates a perspective front view of the plasma device 400 when the front cover 414 is removed; FIG. 4C schematically illustrates a perspective back view of the plasma device 400 with a back panel 412; FIG. 4D schematically illustrates a perspective back view of the plasma device 400 when part of the back panel 412 is removed; and FIG. 4E schematically illustrates a sectional view of the plasma device 400, along line C-C′ in FIG. 4B.

As illustrated in FIGS. 4A to 4E, the plasma device 400 includes a housing 410 enclosing a plasma treatment space 422 and a component space 424, and a plasma-generating nozzle 100 removably disposed in the plasma treatment space 422. The plasma treatment space 422 may have a negative pressure during operation of the plasma device 400. Specifically, the housing 410 includes a front panel 411, a back panel 412, two side panels 413, and a front cover 414. The housing 410 may be made from an insulating material such as, for example, plastic. The front cover 414 may be made from a transparent material and may be removable attached to the housing 410. As illustrated in FIGS. 4C and 4D, a depressible button 417 is formed on the back panel 412, and may be pressed to release the front cover 414 attached to the housing 410. As illustrated in FIGS. 4A to 4D, the housing 410 further includes a side door 415 disposed on at least one of the side panels 413 of the housing 410 for sample handling. As illustrated in FIG. 4E, a metal frame 416 is disposed in the housing 410 and overlap with the front panel 411, the back panel 412, and the two side panels 413. The metal frame 416 may serve as a reinforcement member that strengthens the structure of the housing 410. The metal frame 416 may also serve as an electromagnetic shield that partially contains the electromagnetic field generated by plasma jet PL in the space enclosed by the housing 410.

As illustrated in the sectional view of FIG. 4E, the plasma device 400 further includes an inner panel 420 that is disposed inside the housing 410 and divides the spaced enclosed by the housing 410 into the plasma treatment space 422 and the component space 424. The plasma-generating nozzle 100 illustrated in FIGS. 1A to 1G is disposed in the plasma treatment space 422, and removably attached to the inner panel 420. A plurality of electrical components such as an intake fan 432, at least one exhaust fan 434, a fused power entry inlet 436, a direct current (DC) power supply circuit 438, a main control circuit 440, a high voltage power supply (HVPS) circuit 442, an interface control circuit 444, and a flow meter 446 are disposed in the component space 424.

In the present embodiment, the running time of the plasma-generating nozzle 100 may be continuously monitored by the main control circuit 440 and, when the plasma-generating nozzle 100, reaches its service life, the main control circuit 440 may transmit a signal reminding the user that the plasma-generating nozzle 100 needs to be replaced. When the plasma-generating nozzle 100 needs to be replaced, the user may press the depressible button 417 formed on the back panel 412 of the housing 410 to release the front cover 414 attached to the housing 410 and expose the plasma-generating nozzle 100, and then press the depressible buttons 150 on the nozzle housing 101 of the plasma-generating nozzle 100 to release the plasma-generating nozzle 100.

As illustrated in FIGS. 4B and 4E, the inner panel 420 includes a plurality of openings 426 for passing an exhaust gas from the plasma treatment space 422 to the component space 424. The exhaust gas may include the working gas for plasma generation, as well as other gases, such as ozone, generated by the plasma.

As illustrated in FIGS. 4D and 4E, the intake fan 432 is disposed in the component space 424 and on the metal frame 416. The intake fan 432 is connected to the plasma-generating nozzle 100 for supplying the working gas to the plasma-generating nozzle 100. Specifically, the intake fan 432 sends the working gas to the plasma-generating channel 110 of the plasma-generating nozzle 100 for plasma generation, and to the cooling channel 120 of the plasma-generating nozzle 100 for cooling down the electrodes 130. The working gas may contain, for example, air, argon, helium, nitrogen, or a mixture thereof. When the working gas contains air, the intake fan 432 may be directly exposed to the ambient environment of the plasma device 400 to receive the air from the ambient environment. When the working gas contains argon, helium, nitrogen, or a mixture thereof, the intake fan 432 may be connected to a gas supplier (not illustrated) to receive the working gas.

As illustrated in FIGS. 4D and 4E, two exhaust fans 434 are disposed in the component space 424 and on the metal frame 416. The exhaust fans 434 may be configured to remove the exhaust gas that flows from the plasma treatment space 422 through the plurality of openings 426 formed on the inner panel 420 to the component space 424 for discharge. An ozone filter 460 may be further disposed at an outlet of the exhaust fans 434 to absorb the ozone included in the exhaust gas discharged by the exhaust fans 434. The ozone filter 460 may include activated carbon. The plasma device 400 in the embodiment illustrated in in FIGS. 4A to 4E includes two exhaust fans 434. Alternatively, in other embodiments, the plasma device 400 may include one exhaust fan, or three or more exhaust fans.

As illustrated in FIGS. 4D and 4E, the exhaust fans 434 are spaced apart from the intake fan 432. As a result, the exhaust gas discharged by the exhaust fans 434 may not flow into the plasma-generating nozzle 100 via the intake fan 432, and the working gas may flow into the plasma-generating nozzle 100 through the intake fan 432.

As illustrated in FIG. 4E, the flow meter 446 is disposed in the component space 424 at an inlet of the plasma-generating nozzle 100. The flow meter 446 may be configured to monitor a flow of the working gas that enters the plasma-generating nozzle 100 and feedback the monitoring result to the main control circuit 440. Additionally, a speed of the exhaust fan 434 may be monitored and fed back to the main control circuit 440. The main control circuit 440 may control both of the intake fan 432 and the exhaust fans 434 based on the monitoring result. Because the working gas flow may allow a stable plasma jet PL to be generated, controlling the intake fan 432 based on the flow of the working gas that enters the plasma-generating nozzle 100 may help to ensure stable plasma generation.

A flow rate of the exhaust gas generated by the exhaust fans 434 may be greater than a flow rate of the working gas generated by the intake fan 432. As a result, the plasma treatment space 422 may have a negative pressure comparing to the ambient environment during operation of the plasma device 400. During a treatment process by the plasma device 400, a user may open the side door 415 and hold a treatment sample in the plasma treatment space 422, or a sample holder 710 (illustrated in FIG. 7) on which the treatment sample may be mounted in the plasma treatment space 422, such that the plasma generated by the plasma-generating nozzle 100 may impinge on the treatment sample. If the plasma treatment space 422 does not have a negative pressure comparing to the ambient environment, the ozone generated by the plasma in the plasma treatment space 422 may flow through the opening side door 415 into the ambient environment, contaminating the environment. In the present embodiment, because the plasma treatment space 422 has a negative pressure comparing to the ambient environment, the ozone generated by the plasma in the plasma treatment space 422 may not flow through the opening side door 415 into the ambient environment. As a result, contamination of the ambient environment may be reduced.

As illustrated in FIG. 4A, the plasma device 400 further includes a user interface 470 disposed on the front panel 411 of the housing 410. The user interface 470 includes an input panel 471 and a display panel 475. The input panel 471 includes a first control button 472 being depressible for receiving a user input for starting, pausing, or stopping the plasma treatment process, and a second control button 473 and a third control button 474 being depressible for receiving a user input for setting a time period for the plasma treatment process. The second control button 473 may be used to increase the time period, and the third control button 474 may be used to decrease the time period; or vice versa. The display panel 475 may be configured to display an amount of time remaining in the time period for the plasma treatment process or an amount of time elapsed after starting the plasma treatment process. The display panel 475 may also configured to display an error code when an error occurs. For example, the display panel 475 may be a 7-segment screen.

As illustrated in FIGS. 4C and 4D, the plasma device 400 further includes a first reset button 481 and a second reset button 482 disposed on the back panel 412 of the housing 410. The first reset button 481 may be depressible to reset a running time of the plasma-generating nozzle 100. The second reset button 482 may be depressible to reset a running time of the ozone filter 460. The fused power entry inlet 436 is also disposed on the back panel 412 and connectable to an external power source (not illustrated) to receive electrical power.

As illustrated in FIG. 4E, the plasma device 400 further include a first installation sensor 491, a second installation sensor 492, and a third installation sensor 493 disposed in the component space 424. The first installation sensor 491 is disposed on the inner panel 420 and configured to detect an installation state of the plasma-generating nozzle 100. For example, the first installation sensor 491 may be a limit switch, which may be activated by the pressing structure 160 of the plasma-generating nozzle 100 illustrated in FIGS. 1A to 1E. When the user starts the plasma treatment process by pressing the first control button 472 on the user interface 470, the first installation sensor 491 may transmit an alert signal to the main control circuit 440 if the plasma-generating nozzle 100 is not properly installed. Additionally, or alternatively, when the plasma-generating nozzle 100 is properly installed, the installation sensor 491 may transmit a signal to the main control circuit 440 confirming that the plasma-generating nozzle 100 is properly installed. The main control circuit 440 may be configured to, in response to receiving the alert signal indicating that the plasma-generating nozzle 100 is not properly installed, stop the plasma treatment process and control the display panel 475 on the user interface 470 to display an error code indicating that the plasma-generating nozzle 100 is not properly installed. The second installation sensor 492 is disposed on the metal frame 416, and may be configured to detect an installation state of the front cover 414 and transmit an alert signal to the main control circuit 440 when the front cover 414 is not properly installed. The third installation sensor 493 is disposed on the back panel 412, and may be configured to detect an installation state of the ozone filter 460 and transmit an alert signal to the main control circuit 440 when the ozone filter 460 is not properly installed. The structures and the functions of the second and third installation sensors 492 and 493 may be similar to that of the first installation sensor 491. Therefore, detailed descriptions of the second and third installation sensors 492 and 493 will not be repeated in the present disclosure.

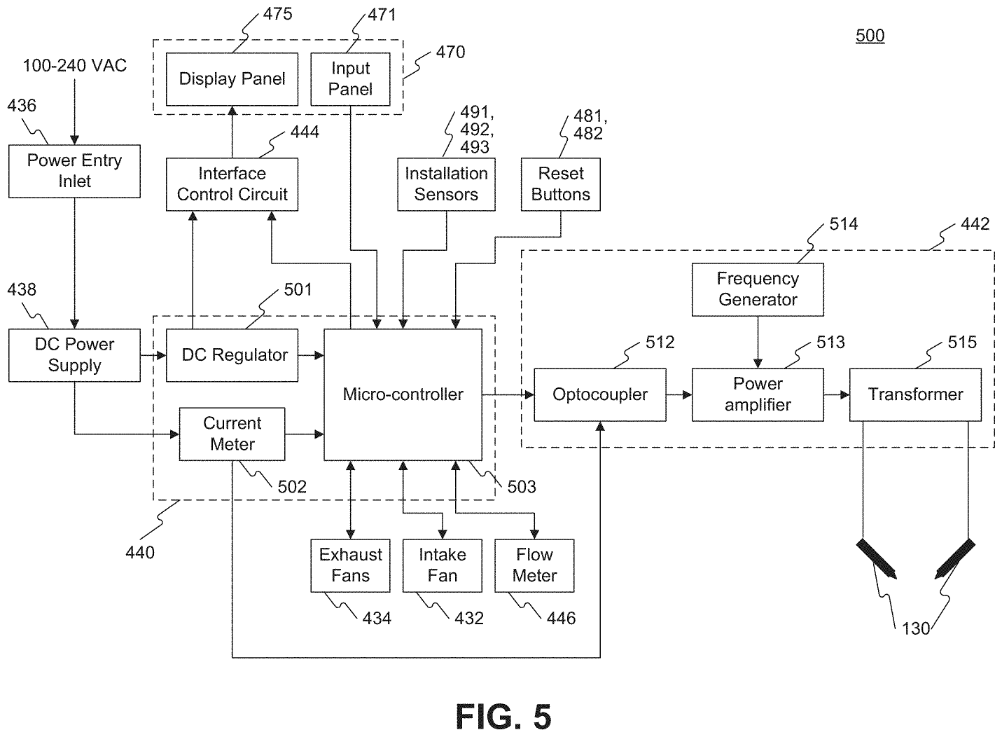

FIG. 5 schematically illustrates an electrical system 500 of the plasma device 400, consistent with an embodiment of the present disclosure. As illustrated in FIG. 5, the electrical system 500 includes the intake fan 432, the exhaust fans 434, the fused power entry inlet 436, the DC power supply circuit 438, the main control circuit 440, the HVPS circuit 442, the interface control circuit 444, the flow meter 446, the first and second reset buttons 481 and 482, and the first to third installation sensors 491-493.

The fused power entry inlet 436 is connectable to an external power source such as, for example, a 100 V to 240V Alternating Current (AC) power source to receive an AC power. The DC power supply circuit 438 is connected to the fused power entry inlet 436 to receive the AC power and is configured to convert the AC power to DC power.

The main control circuit 440 includes a DC regulator 501, a current meter 502, and a micro-controller 503. The DC regulator 501 is connected to the DC power supply circuit 438 to receive DC power and supply the DC power to the micro-controller 503 and the interface control circuit 444. The current meter 502 is connected to the HVPS circuit 442 and may be configured to monitor an input current and an output current of the HVPS circuit 442 and send the monitored result to the micro-controller 503, so that a working state of the HVPS circuit 442. A preferable range of the input current of the HVPS circuit 442 may be 6.5±0.5 A. When the current is over a predetermined limit, the micro-controller 503 may be configured to cut off the power supply to the HVPS circuit 442 and control the display panel 475 to display an error code.

The HVPS circuit 442 includes an optocoupler 512, a power amplifier 513, a frequency generator 514, and a transformer 515. The optocoupler 512 is connected between the micro-controller 503 and the power amplifier 513, and configured to isolate the micro-controller 503 from the power amplifier 513, and to transmit control signals from the micro-controller 503 to the power amplifier 513. As a result, the micro-controller 503 may be protected from conductive emissions generated by the other components in the HVPS circuit 442.

The power amplifier 513 is coupled to the frequency generator 514 to produce a large output voltage swing from a relatively small input signal voltage. The frequency generator 514 is coupled to the power amplifier 513 and may generate a frequency ranging from 21 kHz to 80 kHz, preferable 22 kHz to 23 kHz. As a result, the power amplifier 513 may output electrical power having a duty cycle ranging from 5% to 95%, preferably 30% to 50%, and power ranging from 24 W to 72 W, preferably 72 W. The transformer 515 is coupled to the power amplifier 513 and may transform the electrical power output from the power amplifier 513, and output the transformed electrical power to the pair of electrodes 130 in the plasma-generating nozzle 100. The transformer 515 may have a dielectric strength of 14 kV and a maximum power output of 100 W.

The micro-controller 503 may be configured to estimate an electrode usage based on the monitored results received from the current meter 502. The micro-controller 503 may be configured to adjust the frequency and duty-cycle of the HVPS circuit 442 to facilitate stable plasma generation.

Over time, the resistance between the pair of electrodes 130 may increase as the gap between the electrodes 130 becomes larger. This may cause an output current to drop. The current meter 502 may detect the change in the output current of the HVPS circuit 442 and notify the micro-controller 503 via electrical signals. The micro-controller 503 may then increase the frequency or duty-cycle to increase the output power of the HVPS circuit 442. A higher output power may help keep plasma generation stable when longer distances occur between the electrodes 130.

The interface control circuit 444 may control the display panel 475 in the user interface 470 according to various control signals received from the micro-controller 503. The input panel 471 may receive various user input for receiving a user input for starting, pausing, or stopping a plasma treatment process, and for setting a time period for the plasma treatment process, and transmits signals to the micro-controller 503 representing the various user input.

The flow meter 446 may be configured to monitor the working air flow that enters the plasma-generating nozzle 100 and transmits the monitored result to the micro-controller 503. The micro-controller 503 may be configured to control the intake fan 432 and the exhaust fans 434 based on the monitored air flow, and to ensure stable plasma generation.

The first reset button 481 may be depressible to reset the running time of the plasma-generating nozzle 100. The second reset button 482 may be depressible to reset the running time of the ozone filter 460. The micro-controller 503 may be configured to monitor the running time of each one of the plasma-generating nozzle 100 and the ozone filter 460, and to transmit a replacement reminder signal to the interface control circuit 444 when the running time of the plasma-generating nozzle 100 or the ozone filter 460 reaches a predetermined amount of time. The interface control circuit 444 may then controls the display panel 475 in the user interface 470 to display an indicator (e.g., a code, a symbol, etc.) indicating that the plasma-generating nozzle 100 or the ozone filter 460 needs to be replaced. The plasma-generating nozzle 100 may need to be replaced when it reaches its service life. In the present embodiment, the running time of the plasma-generating nozzle 100 may be continuously monitored by the micro-controller 503 of the main control circuit 440 and the plasma-generating nozzle 100 may be replaced when it reaches its service life, thus the power consumption of the plasma device 400 may be reduced,

The first to third installation sensors 491, 492, and 493 may be configured to detect an installation state of each of the front cover 414 of the housing 410, the plasma-generating nozzle 100, and the ozone filter 460, and to transmit an alert signal to the micro-controller 503 when at least one of the front cover 414, the plasma-generating nozzle 100, and the ozone filter 460 is not installed. The micro-controller 503 may be configured to, in response to receiving the alert signal, transmit a control signal to the HVPS circuit 442 to stop supplying power to the electrodes 130 in the plasma-generating nozzle 100, thereby stopping a plasma treatment process. In addition, in response to receiving the alert signal, the micro-controller 503 may be configured to instruct the interface control circuit 444 to control the display panel 475 to display an error code.

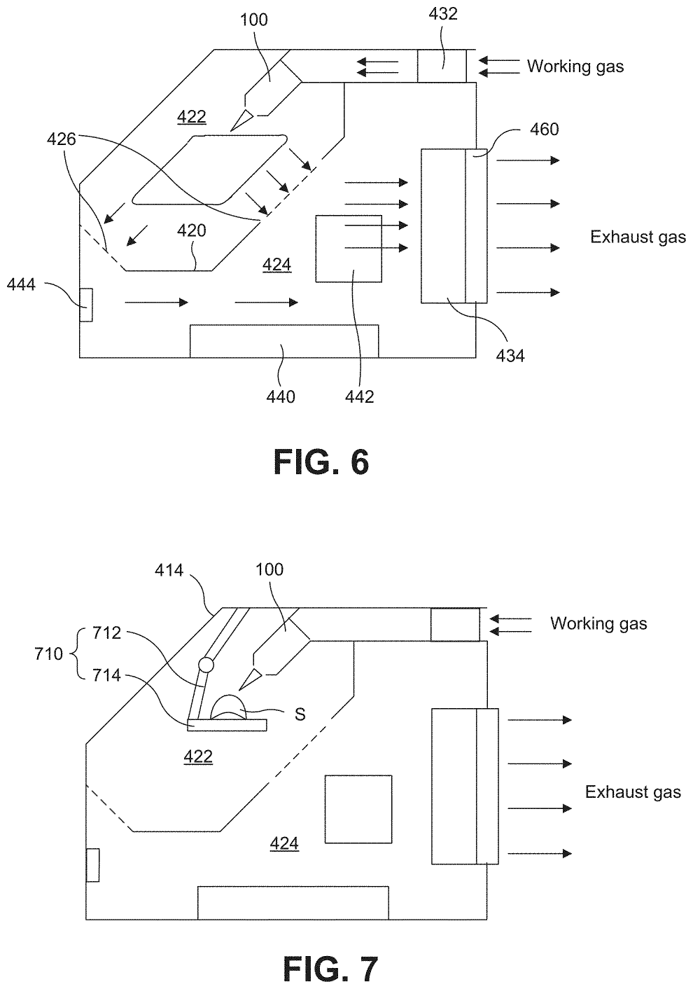

FIG. 6 schematically illustrates a sectional view of the plasma device 400 with air flows, consistent with an embodiment of the present disclosure. In FIG. 6, the same parts of the plasma device 400 are designated by the same reference characters as in FIGS. 4A to 4E.

As illustrated in FIG. 6, the intake fan 432 may receive the working gas and sends the working gas to the plasma-generating nozzle 100 disposed in the plasma treatment space 422 for plasma generation. The exhaust gas generated in the plasma treatment space 422 may be forced by the exhaust fans 434 to flow from the plasma treatment space 422 to the component space 424 through the openings 426 formed on the inner panel 420, passing through the electrical components such as the main control circuit 440, the HVPS circuit 442, the interface control circuit 444, in the component space 424, and the ozone filter 460, before it is vented outside of the plasma device 400. The exhaust gas passing through the electrical components may help to cool down these electrical components. As a result, extra fans or cooling gases may not be needed to cool down the electronic components.

FIG. 7 schematically illustrates a sectional view of the plasma device 400 consistent with another embodiment of the present disclosure. As illustrated in FIG. 7, an adjustable and foldable holder 710 is disposed inside the plasma treatment space 422 and attached to the front cover 414 of the housing 410. The adjustable and foldable holder 710 includes an adjustable and foldable arm 712 and a susceptor 714 connected to the adjustable and foldable arm 712. The treatment sample S may be mounted on the susceptor 714. The adjustable and foldable arm 712 may be adjusted to a position such that the plasma jet PL generated by the plasma-generating nozzle 100 may impinge on the treatment sample S. By using the adjustable and foldable holder 710, it is unnecessary for the user to open the side door 415 and holding the treatment sample during the treatment process.

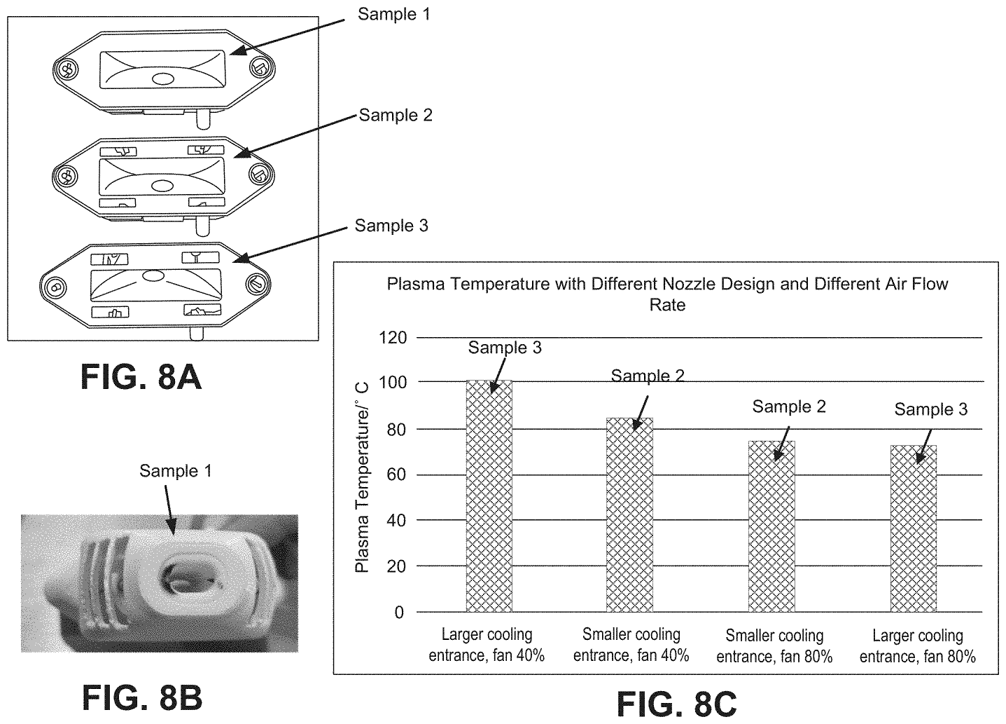

FIG. 8A shows top views of three different samples of plasma-generating nozzles. Sample 1 is a comparative example of a plasma-generating nozzle which has an inlet opening for a plasma-generating channel but no inlet openings for a cooling channel. Sample 2 is an example of a plasma-generating nozzle consistent with an embodiment of the present disclosure, which has an inlet opening for a plasma-generating channel and four relatively smaller inlet openings for a cooling channel. Sample 3 is another example of a plasma-generating nozzle consistent with an embodiment of the present disclosure, which has an inlet opening for a plasma-generating channel and four relatively larger inlet openings for a cooling channel. FIG. 8B is a photo of a bottom view of Sample 1, which shows the nozzle (without cooling channel) is burned during the plasma generation process. FIG. 8C is a graph showing plasma temperatures generated by Sample 2 and Sample 3 with different duty cycles of exhaust fans.

As shown in FIG. 8B, when the plasma-generating nozzle does not include any inlet opening for a cooling channel (Sample 1), no cooling gas may pass through the electrodes in the plasma-generating nozzle during the plasma generation process. As a result, the temperature of the electrodes disposed at the bottom of the plasma-generating nozzle may be increased by the high voltage applied thereto, thereby increasing the temperature of the generated plasma. Consequently, the bottom of the plasma-generating channel may be burned and damaged by the high temperature of the plasma.

By contrast, the plasma-generating nozzles of Sample 2 and Sample 3 according to the embodiments of the present disclosure both have inlet openings for a cooling channel. Thus, the working gas may enter the cooling channel via the inlet openings, and pass through the part of the electrodes disposed at the bottom of the cooling channel, thereby cooling the electrodes during the plasma generation. Consequently, the plasma-generating nozzles of Sample 2 and Sample 3 are not damaged by the plasma.

As shown in FIG. 8C, the plasma temperatures may be sequentially decreased for: Sample 3 (relatively larger inlets for cooling channel) with a fan duty cycle of 40% (relatively smaller air flow), Sample 2 (relatively smaller inlets for cooling channel) with a fan duty cycle of 40% (relatively smaller air flow), Sample 2 (relatively smaller inlets for cooling channel) with a fan's duty cycle of 80% (relatively larger air flow), and Sample 3 (relatively larger inlets for cooling channel) with a fan duty cycle of 80% (relatively larger air flow). Therefore, plasma temperature can be controlled by adjusting air flow or the size of gas inlet opening.

While illustrative embodiments have been described herein, the scope of the present disclosure covers any and all embodiments having equivalent elements, modifications, omissions, combinations (e.g., of aspects across various embodiments), adaptations and/or alterations as would be appreciated by those skilled in the art based on the present disclosure. For example, features included in different embodiments shown in different figures may be combined. The limitations in the claims are to be interpreted broadly based on the language employed in the claims and not limited to examples described in the present specification or during the prosecution of the application. The examples are to be construed as non-exclusive. It is intended, therefore, that the specification and examples be considered as illustrative only, with a true scope and spirit being indicated by the following claims and their full scope of equivalents.

What is claimed is:

1. A plasma-generating nozzle, comprising:
a plasma-generating channel;
a cooling channel at least partially surrounding the plasma-generating channel; and
a pair of electrodes partially disposed in the plasma-generating channel for generating plasma.

2. The plasma-generating nozzle of claim 1, wherein
the plasma-generating channel includes a first gas inlet opening for receiving a working gas and a first gas outlet opening for discharging the working gas,
the cooling channel includes a second gas inlet opening for receiving the working gas and a second gas outlet opening for discharging the working gas,
each of the electrodes having a tip and a connection end, at least a portion of each of the tips being disposed at the first gas outlet opening of the plasma-generating channel, and at least a portion of each of the connection ends being disposed at the second gas outlet opening of the cooling channel.

3. The plasma-generating nozzle of claim 1, wherein a grind angle θ of each of the electrode tips ranges from 0° to 180°, and an angle between the electrode tips ranges from θ to 180°.

4. The plasma-generating nozzle of claim 2, wherein the plasma-generating channel includes a funnel shaped part connected to the first gas inlet opening.

5. The plasma-generating nozzle of claim 4, wherein the plasma-generating channel further includes a cylindrical shaped part connected between the funnel shaped part and the first gas outlet opening.

6. The plasma-generating nozzle of claim 1, the plasma-generating channel is separated from the cooling channel.

7. The plasma-generating nozzle of claim 1, further comprising an electrode holder disposed inside the cooling channel and includes a dielectric material with heat resistance and thermal conductivity,
wherein the electrode holder includes a plurality of openings for passing a working gas.

8. The plasma-generating nozzle of claim 7, further comprising a pair of electrode connectors fixed to the electrode holder, the pair of electrode connectors are configured to connect the pair of electrodes to the electrode holder.

9. The plasma-generating nozzle of claim 1, wherein at least a part of the plasma-generating channel surrounding the electrode tips includes a dielectric material.

10. The plasma-generating nozzle of claim 1, wherein the working gas includes air, argon, helium, nitrogen, or a mixture thereof, and a flow rate of the working gas ranges from 25 LPM to 350 LPM.

11. A plasma device, comprising:
a housing enclosing a plasma treatment space and a component space, wherein the plasma treatment space has a negative pressure during operation of the plasma device; and
a plasma-generating nozzle removably disposed in the plasma treatment space.

12. The plasma device of claim 11, further comprising an inner panel disposed inside the housing and dividing a space enclosed by the housing into the plasma treatment space and the component space,
wherein the inner panel includes a plurality of openings for passing an exhaust gas from the plasma treatment space to the component space.

13. The plasma device of claim 12, further comprising:
an intake fan disposed in the component space and connected to the plasma-generating nozzle and configured to supply a working gas to the plasma-generating nozzle; and
an exhaust fan disposed in the component space and configured to remove the exhaust gas from the plasma treatment space through the plurality of openings to the component space for discharge,
wherein the intake fan and exhaust fan are spaced apart from each other, and a flow rate of the exhaust gas generated by the exhaust fan is greater than a flow rate of the working gas generated by the intake fan.

14. The plasma device of claim 13, further comprising an ozone filter disposed at an outlet of the exhaust fan.

15. The plasma device of claim 13, further comprising a flow meter disposed in the component space at an inlet of the plasma-generating nozzle, and configured to monitor a flow of the working gas that enters the plasma-generating nozzle, and
wherein the intake fan and the exhaust fan are controlled based on the monitored flow.

16. The plasma device of claim 11, further comprising:
a user interface disposed on the housing; and
a plurality of electrical components including a fused power entry inlet, a DC power supply circuit, a main control circuit, a high voltage power supply circuit, and an interface control circuit disposed in the component space,
wherein the main control circuit is configured to determine a running time of each one of the plasma-generating nozzle and the ozone filter, and to transmit a replacement reminder signal to the user interface when the running time of the plasma-generating nozzle or the ozone filter reaches a predetermined amount of time.

17. The plasma device of claim 16, further comprising installation sensors disposed in the housing and configured to detect an installation state of each of a front cover of the housing, the plasma-generating nozzle, and the ozone filter, and to transmit an alert signal to the main control circuit when at least one of the front cover, the plasma-generating nozzle, and the ozone filter is not installed,
wherein the main control circuit is configured to, in response to receiving the alert signal, stop a plasma treatment process and control the user interface to display an error code.

18. The plasma device of claim 16, wherein the user interface comprises:
an input panel for receiving a user input for starting, pausing, or stopping a plasma treatment process, and for setting a time period for the plasma treatment process; and
a display panel for displaying an amount of time remaining in the time period for the plasma treatment process or an amount of time elapsed after starting the plasma treatment process, and displaying an error code when an error occurs.

19. The plasma device of claim 16, wherein the high voltage power supply circuit comprises an optocoupler connected between a micro-controller in the main control circuit and other components in the high voltage power supply circuit and configured to isolate the micro-controller from the other components in the high voltage power supply circuit.

20. The plasma device of claim 11, further comprising:
a side door disposed on the housing for sample handling; or
an adjustable and foldable holder attached to the housing for holding a sample for plasma treatment.
